(19) United States
(12) Patent Application Publication
(10) Pub. No.: US 2026/0206434 A1
(43) Pub. Date: Jul. 16, 2026

(54) DISPLAY DEVICE AND ELECTRONIC DEVICE

(71) Applicant: Samsung Display Co., Ltd., Yongin-si (KR)

(72) Inventors: Young Woo PARK, Yongin-si (KR); Tae Sik KIM, Yongin-si (KR); Hyun Wook LEE, Yongin-si (KR); Taek Ju JUNG, Yongin-si (KR); Eui Kang HEO, Yongin-si (KR)

(21) Appl. No.: 19/309,773

(22) Filed: Aug. 26, 2025

(30) Foreign Application Priority Data
Jan. 13, 2025 (KR) 10-2025-0004897

(51) Int. Cl. H10K 59/131

(52) U.S. Cl. CPC H10K 59/131

(57) ABSTRACT

A display device includes a substrate including a display area including a plurality of pixels and a non-display area; data lines extended from the display area; a display driver circuit in the non-display area and on one side of the display area; pad electrodes connected to the display driver circuit; extension lines extended from the pad electrodes; interconnect lines connecting the data lines with the extension lines, and including a first interconnect line and a second interconnect line spaced apart from each other; and a contact pattern overlapping with one of the second interconnect line and the extension lines, wherein the first interconnect line is connected to an extension line through a first contact portion, wherein the second interconnect line is connected to the contact pattern through a second contact portion, and wherein a size of the second contact portion is larger than a size of the first contact portion.

### CROSS-REFERENCE TO RELATED APPLICATION

The present application claims priority to and the benefit of Korean Patent Application No. 10-2025-0004897, filed on Jan. 13, 2025, in the Korean Intellectual Property Office, the entire disclosure of which is incorporated herein by reference.

### BACKGROUND

### 1. Field

Aspects of the present disclosure relate to a display device and an electronic device.

### 2. Description of the Related Art

As the information-oriented society evolves, various demands for display devices are ever increasing. For example, display devices are being employed by a variety of electronic devices such as smart phones, digital cameras, laptop computers, navigation devices, smart watches, and smart televisions. Display devices may be flat panel display devices such as a liquid-crystal display device, a field emission display device, and an organic light-emitting display device.

A display device may include a plurality of pixels. Each of the plurality of pixels may include a light-emitting element, a driving transistor for controlling the amount of driving current supplied from a power supply to the light-emitting element according to a voltage at the gate electrode, a plurality of switching elements performing switching in response to scan signals from scan lines, and a plurality of capacitors.

A display device includes a display area where images are displayed, and a non-display area around the display area. In the non-display area, a display driver circuit that applies signals to the display area, and a plurality of lines connected to the display driver circuit are arranged. The display driver circuit may be mounted directly on the display device by a chip on glass (COG) technique. Unfortunately, there is a problem in separating the display driver circuit mounted by the COG technique for rework that spider lines under the display driver circuit may be torn off, making the rework difficult.

The above information disclosed in this Background section is only for enhancement of understanding of the background of the invention and therefore it may contain information that does not form.

### SUMMARY

Aspects of the present disclosure are directed to a display device that allows for rework of a display driver circuit by improving adhesive properties of interconnect lines (e.g., spider lines), and an electronic device including the same.

It should be noted that objects of the present disclosure are not limited to the above-mentioned object; and other objects of the present disclosure will be apparent to those skilled in the art from the following descriptions.

According to some embodiments of the present disclosure, there is provided a display device including: a substrate including a display area including a plurality of pixels and a non-display area located around the display area; data lines extended from the display area; a display driver circuit in the non-display area and on one side of the display area; pad electrodes connected to the display driver circuit; extension lines extended from the pad electrodes; interconnect lines connecting the data lines with the extension lines, and including a first interconnect line and a second interconnect line spaced apart from each other; and a contact pattern overlapping with one of the second interconnect line and the extension lines, wherein the first interconnect line is connected to an extension line of the extension lines through a first contact portion, wherein the second interconnect line is connected to the contact pattern through a second contact portion, and wherein a size of the second contact portion is larger than a size of the first contact portion.

In some embodiments, the contact pattern is connected to the extension line overlapping with the contact pattern through a third contact portion.

In some embodiments, the size of the second contact portion is larger than a size of the third contact portion.

In some embodiments, the first interconnect line and the second interconnect line are at different layers.

In some embodiments, a width of the contact pattern is greater than a width of the extension line.

In some embodiments, a width of the second interconnect line is greater than a width of the contact pattern.

In some embodiments, the second interconnect line protrudes further in a direction toward the display driver circuit than the first interconnect line.

In some embodiments, each of the first interconnect line and the second interconnect line includes a first region and a second region, and wherein the second region is bent from the first region and closer to the display driver circuit.

In some embodiments, a width of the first region of the first interconnect line is equal to a width of the first region of the second interconnect line.

In some embodiments, a length of the second region of the second interconnect line is different from a length of the first region of the first interconnect line.

In some embodiments, the length of the second region of the second interconnect line is larger than the length of the first region of the first interconnect line.

In some embodiments, a length of the second region of the first interconnect line is different from a length of another first interconnect line, and wherein a length of the second region of the second interconnect line is different from a length of another second interconnect line.

In some embodiments, lengths of the second regions of the first interconnect lines and lengths of the second regions of the second interconnect lines increase along a direction.

According to some embodiments of the present disclosure, there is provided a display device including: a substrate; extension lines arranged on the substrate; a plurality of insulating layers arranged on the extension lines; a first interconnect line and a contact pattern arranged on the plurality of insulating layers, and the contact pattern is spaced apart from the first interconnect line; a first via layer arranged on the contact pattern; a second interconnect line arranged on the first via layer; pad electrodes arranged on the plurality of insulating layers and overlapping with the extension lines; and a display driver circuit arranged on the pad electrodes, wherein the first interconnect line is connected to one of the extension lines through a first contact portion penetrating the plurality of insulating layers, wherein the second interconnect line is connected to the contact pattern through a second contact portion penetrating the first via layer, wherein the contact pattern is connected to another one of the extension lines through a third contact portion penetrating the plurality of insulating layers, and wherein a size of the second contact portion is larger than a size of the first contact portion and a size of the third contact portion.

In some embodiments, the pad electrodes are connected to the extension lines through pad contact holes penetrating the plurality of insulating layers, the pad electrodes includes a lower pad electrode in contact with the extension lines, and an upper pad electrode located on the lower pad electrode, the extension lines include a first conductive layer, the lower pad electrode, the first interconnect line, and the contact pattern include a second conductive layer, and the upper pad electrode and the second interconnect line include a third conductive layer.

In some embodiments, the display device further includes: an anisotropic conductive film between the display driver circuit and the pad electrodes and including a conductive ball, wherein the display driver circuit includes bumps, and wherein the bumps and the pad electrodes are connected through the conductive ball.

In some embodiments, the anisotropic conductive film covers at least a portion of the second interconnect line and is in contact with the second interconnect line.

In some embodiments, the display device further includes: a second via layer located on the second interconnect line, wherein the second via layer exposes at least a portion of the second interconnect line, and wherein the anisotropic conductive film covers a portion of the second via layer and the second interconnect line exposed by the second via layer.

In some embodiments, the display driver circuit overlaps with the extension lines and does not overlap with the first interconnect line or the second interconnect line.

According to some embodiments of the present disclosure, there is provided an electronic device including a display device, a display module, a processor, a memory and a power module, the display device including: a substrate including a display area including a plurality of pixels and a non-display area located around the display area; data lines extended from the display area; a display driver circuit in the non-display area and on one side of the display area; pad electrodes connected to the display driver circuit; extension lines extended from the pad electrodes; interconnect lines connecting the data lines with the extension lines, and including a first interconnect line and a second interconnect line spaced apart from each other; and a contact pattern overlapping with one of the second interconnect line and the extension lines, wherein the first interconnect line is connected to an extension line of the extension lines through a first contact portion, wherein the second interconnect line is connected to the contact pattern through a second contact portion, and wherein a size of the second contact portion is larger than a size of the first contact portion.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view showing a display device according to some embodiments of the present disclosure.

FIG. 2 is a plan view showing a display panel of a display device according to some embodiments of the present disclosure.

FIG. 3 is a side view showing a display panel of a display device according to some embodiments of the present disclosure.

FIG. 4 is a plan view showing sub-pixels and signal lines of a display device according to some embodiments of the present disclosure.

FIG. 5 is a cross-sectional view showing a structure of a sub-pixel of a display panel according to some embodiments of the present disclosure.

FIG. 6 is a plan view showing a non-display area of a display panel according to some embodiments of the present disclosure.

FIG. 7 is a plan view showing a portion of a non-display area of a display panel according to some embodiments of the present disclosure.

FIG. 8 is a plan view showing the interconnect lines (e.g., spider lines) shown in FIG. 7, according to some embodiments of the present disclosure.

FIG. 9 is a cross-sectional view taken along the line Q1-Q1′ of FIG. 7, according to some embodiments of the present disclosure.

FIG. 10 is a cross-sectional view taken along the line Q2-Q2′ of FIG. 7, according to some embodiments of the present disclosure.

FIG. 11 is a cross-sectional view taken along the line Q3-Q3′ of FIG. 7, according to some embodiments of the present disclosure.

FIG. 12 is a cross-sectional view taken along the line Q4-Q4′ of FIG. 7, according to some embodiments of the present disclosure.

FIG. 13 is a cross-sectional view taken along the line Q2-Q2′ of FIG. 7, according to some embodiments of the present disclosure.

FIGS. 14 and 15 are cross-sectional views showing a rework process of a display driver circuit, according to some embodiments of the present disclosure.

FIGS. 16 and 17 are cross-sectional views showing a display device according to some embodiments of the present disclosure.

FIG. 18 is a cross-sectional view showing a display device according to some other embodiments of the present disclosure.

FIG. 19 is a block diagram of an electronic device according to some embodiments of the present disclosure.

FIG. 20 is a view showing electronic devices according to a variety of embodiments of the present disclosure.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described with reference to the accompanying drawings.

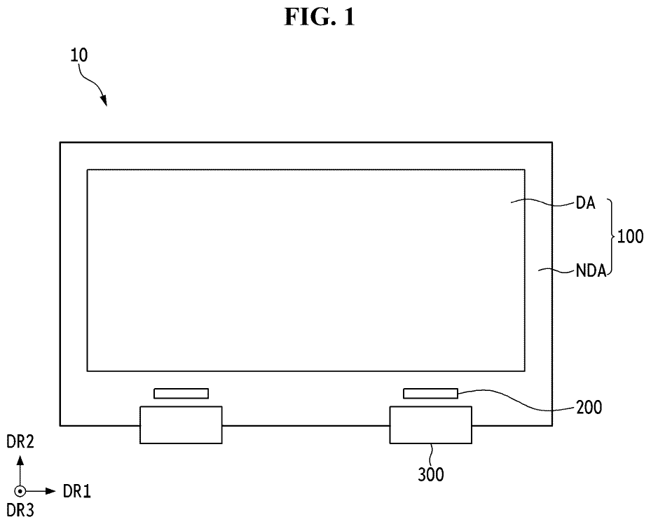

FIG. 1 is a plan view showing a display device according to some embodiments of the present disclosure.

Referring to FIG. 1, a display device 10 is for displaying moving images or still images. The display device 1 may be used as the display screen of portable electronic devices such as mobile phones, smart phones, tablet PCs, smart watches, watch phones, mobile communications terminals, electronic notebooks, electronic books, portable multimedia players (PMPs), navigation devices and ultra mobile PCs (UMPCs), as well as the display screen of various products such as televisions, notebooks, monitors, billboards and internet of things (IOT) devices.

The display device 10 may be a light-emitting display device such as an organic light-emitting display device using organic light-emitting diodes, an inorganic light-emitting display device including an inorganic semiconductor, and a micro light-emitting display device using micro or nano light-emitting diodes (micro LEDs or nano LEDs). In the following description, an organic light-emitting display device is described as an example of the display device 10. It is, however, to be understood that the present disclosure is not limited thereto.

The display device 10 includes a display panel 100, a display driver circuit 200, and a circuit board 300.

The display panel 100 may be formed in a rectangular plane having longer sides in the first direction DR1 and shorter sides in the second direction DR2 intersecting the first direction DR1. In addition, the display panel 100 may have a thickness in the third direction DR3 that is perpendicular to the plane formed by the first direction DR1 and the second direction DR2. Each of the corners where the longer side in the first direction DR1 meets the shorter side in the second direction DR2 may be rounded with a set or predetermined curvature or may be a right angle. The shape of the display panel 100 when viewed from the top (i.e., in a plan view) is not limited to a quadrangular shape, but may be formed in a different polygonal shape, a circular shape, or an elliptical shape. The display panel 100 may be formed flat, but the present disclosure is not limited thereto. For example, the display panel 100 may be formed at left and right ends, and may include a curved portion having a constant curvature or a varying curvature. In addition, the display panel 100 may be rigid, but the present disclosure is not limited thereto. The display panel 100 may be flexible so that it can be curved, bent, folded, or rolled.

The display panel 100 may include a display area DA where images are displayed, and a non-display area NDA around the display area DA. The display area DA may include a plurality of pixels for displaying images. The display area DA and the non-display area NDA will be described later.

The display driver circuit 200 may generate signals and voltages for driving the display panel 100. The display driver circuit 200 may be implemented as an integrated circuit (IC) and may be attached to the display panel 100 by a chip on glass (COG) technique, a chip on plastic (COP) technique, or an ultrasonic bonding. It is, however, to be understood that the present disclosure is not limited thereto. For example, the display driver circuit 200 may be attached on the circuit board 300 by the chip-on-film (COF) technique. In some embodiments, the COG technique will be described as an example.

The circuit board 300 may be attached to one end of the display panel 100. Accordingly, the circuit board 300 may be electrically connected to the display panel 100 and the display driver circuit 200. The display panel 100 and the display driver circuit 200 may receive digital video data, timing signals, and driving voltages through the circuit board 300. The circuit board 300 may be a flexible printed circuit board, a printed circuit board, or a flexible film such as a chip on film.

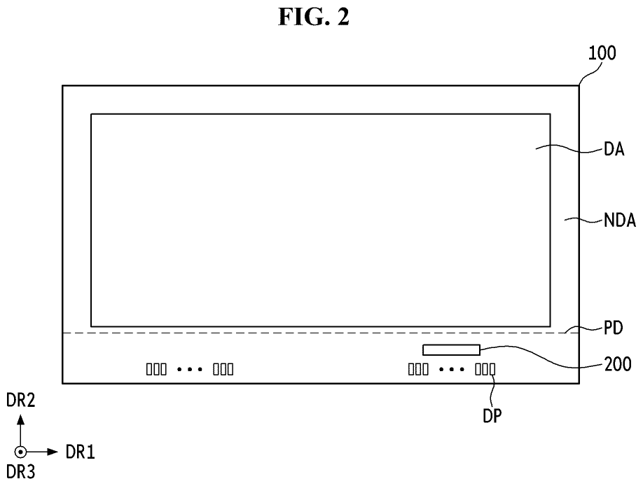

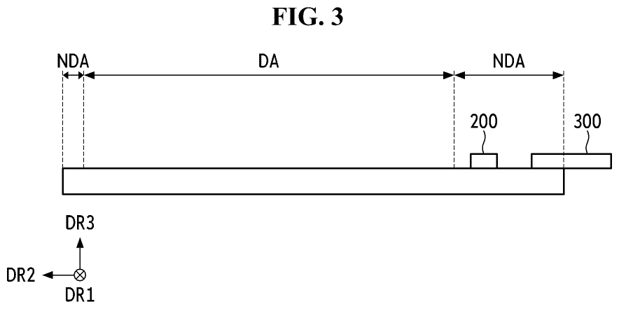

FIG. 2 is a plan view showing a display panel of a display device according to some embodiments of the present disclosure. FIG. 3 is a side view showing a display panel of a display device according to some embodiments of the present disclosure.

Referring to FIGS. 2 and 3, the display panel 100 may include the display area DA and the non-display area NDA.

In the display area DA, images may be displayed. The non-display area NDA may surround the display area DA. The display area DA may occupy most of the area of the display panel 100 when viewed from the top (i.e., in a plan view). The display area DA may be located at the center of display panel 100 when viewed from the top.

The non-display area NDA may surround the display area DA, and may be located on the outer side of the display area DA. The non-display area NDA may be defined as the edge area of the display panel 100.

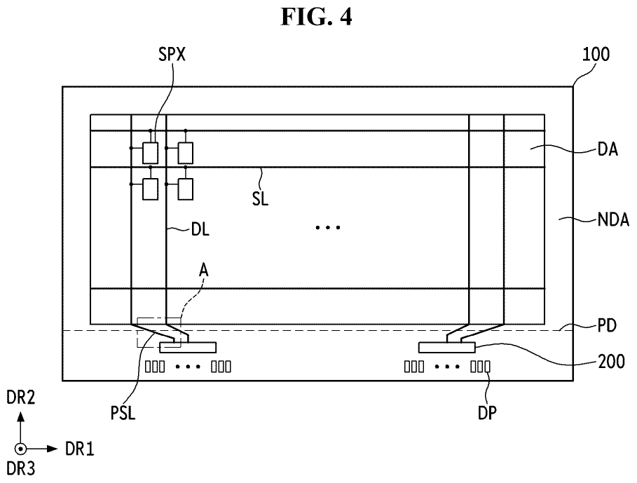

The non-display area NDA may include a pad area PD located on a side. The pad area PD may be located on one side of the display area DA in the second direction DR2 as a portion of the non-display area NDA. The pad area PD may include a plurality of pad signal lines PSL (see, e.g., FIG. 4) connecting a plurality of signal lines in the display area DA with the display driver circuit 200.

In addition, the pad area PD may have a plurality of pads DP and the display driver circuit 200 arranged thereon. The display driver circuit 200 may be attached on driver pads in the pad area PD using a low-resistance, high-reliability material such as an anisotropic conductive film and self-assembly anisotropic conductive paste (SAP). The circuit board 300 may be attached on the pads DP in the pad area PD using a low-resistance, high-reliability material such as an anisotropic conductive film and SAP.

FIG. 4 is a plan view showing sub-pixels and signal lines of a display device according to some embodiments of the present disclosure.

Referring to FIG. 4, the display area DA of the display panel 100 may include sub-pixels SPX, scan lines SL, and data lines DL. The scan lines SL may be extended in the first direction DR1 and arranged spaced apart from each other in the second direction DR2. The data lines DL may be extended in the second direction DR2 and may be spaced apart from one another in the first direction DR1.

Each of the sub-pixels SPX may be connected to a scan line SL and a data line DL. Each of the sub-pixels SPX may include a driving transistor, a plurality of switch elements, a light-emitting element, and a capacitor.

The plurality of switch elements may be controlled by the scan lines SL, and accordingly a data voltage of a data line DL may be applied to the gate electrode of the driving transistor. A plurality of lines for driving circuits of the sub-pixels SPX, such as a scan write line, a scan initialization line, a scan bias line, a voltage initialization line and a voltage (or power) line, may be included.

When the data voltage is applied to the gate electrode, the driving transistor may supply a driving current to the light-emitting element, so that light can be emitted. The light-emitting element may emit light in proportion to the driving current from the driving transistor. The light-emitting element may be an organic light-emitting diode including a first electrode, an organic emissive layer, and a second electrode. In some examples, the light-emitting element may be an inorganic light-emitting diode including a first electrode, an inorganic semiconductor, and a second electrode. In some examples, the light-emitting element may be a micro-or nano-light-emitting diode. The capacitor may hold the data voltage applied to the gate electrode of the driving transistor for a certain period of time.

The non-display area NDA of the display panel 100 may include spider lines (also referred to herein as interconnect lines) SPL connecting data lines DL of the display area DA with the display driver circuit 200. In addition, the non-display area NDA may further include fan-out lines, which connect the scan driver that applies signals to the scan lines with the scan lines SL.

The spider lines SPL may be arranged in the non-display area NDA. The spider lines SPL may be extended to the pad area PD to electrically connect the display area DA with the display driver circuit 200. As another example, each of the spider lines SPL may be connected to another spider line arranged between itself and the display driver circuit 200 to be electrically connected to the display driver circuit 200. A more detailed description thereon will be given below.

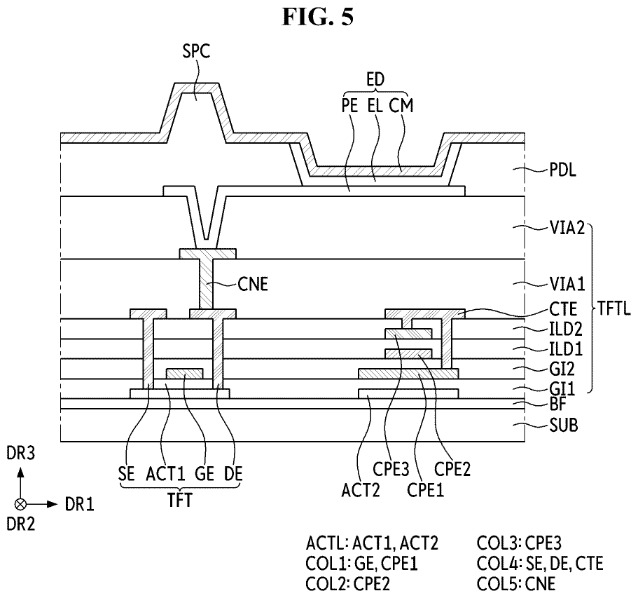

FIG. 5 is a cross-sectional view showing a structure of a sub-pixel of a display panel according to some embodiments of the present disclosure.

Referring to FIG. 5, the display device 10 may include a substrate SUB, a thin-film transistor layer TFTL, and an emission material layer EML. For example, the thin-film transistor layer TFTL and the emission material layer EML may be sequentially arranged on the substrate SUB.

The substrate SUB may be a rigid substrate or a flexible substrate that can be bent, folded, rolled, and so on. The substrate SUB may be made of an insulating material such as glass, quartz and a polymer resin. Examples of the polymer material may include polyethersulphone (PES), polyacrylate (PA), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), or a combination thereof. In some examples, the substrate SUB may include a metallic material.

The thin-film transistor layer TFTL may be located on the substrate SUB. The thin-film transistor layer TFTL may include a buffer layer BF, a semiconductor layer ACTL, a first conductive layer COL1, a second conductive layer COL2, a third conductive layer COL3, a fourth conductive layer COL4, and a fifth conductive layer COL5. In addition, the thin-film transistor layer TFTL may include a plurality of insulating layers, for example, a first gate insulator GI1, a second gate insulator GI2, a first interlayer dielectric layer ILD1, a second interlayer dielectric layer ILD2, a first via layer VIA1, and a second via layer VIA2.

The buffer layer BF may be located on the entire surface of the substrate SUB. The buffer layer BR may be a layer for protecting the thin-film transistor layer TFTL and the emission material layer EML from the moisture permeating through the substrate SUB that is vulnerable to moisture. The buffer layer BF may contain an inorganic material. For example, the buffer layer BF may include at least one of: silicon nitride, silicon oxynitride, silicon oxide, titanium oxide, and aluminum oxide. The buffer layer BF may be made up of a single layer or multiple layers in which multiple layers are stacked on one another.

The semiconductor layer ACTL may be located on the buffer layer BF. The semiconductor layer ACTL may include a first active layer ACT1 and a second active layer ACT2. The first active layer COL1 and the second active layer ACT2 may include a channel of a thin-film transistor. The first active layer COL1 and the second active layer ACT2 may contain polycrystalline silicon or oxide semiconductor.

The first gate insulator GI1 may be located on the semiconductor layer ACTL. For example, the first gate insulator GI1 may cover the first active layer ACT1, the second active layer ACT2, and the buffer layer BF. The first gate insulator GI1 may include at least one of: silicon nitride, silicon oxynitride, silicon oxide, titanium oxide, and aluminum oxide.

The first conductive layer COL1 may be located on the first gate insulator GI1. The first conductive layer COL1 may include a gate electrode GE and a first capacitor electrode CPE1. The gate electrode GE may overlap (e.g., in the plan view) with the first active layer ACT1, and the first capacitor electrode CPE1 may overlap with the second active layer ACT2. The gate electrode GE may overlap with the channel of the first active layer ACT1. The first conductive layer COL1 may be made up of a single layer or multiple layers of one of molybdenum (Mo), aluminum (Al), chromium (Cr), gold (Au), titanium (Ti), nickel (Ni), neodymium (Nd), and copper (Cu), or an alloy thereof.

The second gate insulator GI2 may be located on the first conductive layer COL1. For example, the second gate insulator GI2 may cover the gate electrode GE, the first capacitor electrode CPE1 and the first gate insulator GI1. The second gate insulator GI2 may include at least one of: silicon nitride, silicon oxynitride, silicon oxide, titanium oxide, and aluminum oxide.

The second conductive layer COL2 may be located on the second gate insulator GI2. The second conductive layer COL2 may include a second capacitor electrode CPE2. The second capacitor electrode CPE2 may overlap (e.g., in the plan view) with the first capacitor electrode CPE1. The second conductive layer COL2 may be made up of a single layer or multiple layers of one of molybdenum (Mo), aluminum (Al), chromium (Cr), gold (Au), titanium (Ti), nickel (Ni), neodymium (Nd), and copper (Cu), or an alloy thereof.

The first interlayer dielectric layer ILD1 may be located on the second conductive layer COL2. For example, the first interlayer dielectric layer ILD1 may cover the second capacitor electrode CPE2 and the second gate insulator GI2. The first interlayer dielectric layer ILD1 may include at least one of silicon nitride, silicon oxynitride, silicon oxide, titanium oxide, and aluminum oxide.

The third conductive layer COL3 may be located on the first interlayer dielectric layer ILD1. The third conductive layer COL3 may include a third capacitor electrode CPE3. The third capacitor electrode CPE3 may overlap with the first and second capacitor electrodes CPE1 and CPE2. The third conductive layer COL3 may be made up of a single layer or multiple layers of one of molybdenum (Mo), aluminum (Al), chromium (Cr), gold (Au), titanium (Ti), nickel (Ni), neodymium (Nd), and copper (Cu), or an alloy thereof.

The second interlayer dielectric layer ILD2 may be located on the third conductive layer COL3. For example, the second interlayer dielectric layer ILD2 may cover the third capacitor electrode CPE3. The second interlayer dielectric layer ILD2 may include at least one of: silicon nitride, silicon oxynitride, silicon oxide, titanium oxide, and aluminum oxide.

The fourth conductive layer COL4 may be located on the second interlayer dielectric layer ILD2. The fourth conductive layer COL4 may include a source electrode SE, a drain electrode DE, and a contact electrode CTE. The source electrode SE and the drain electrode DE may be arranged to overlap with the first active layer ACT1 and may be connected to the first active layer ACT1 through contact holes penetrating the first gate insulator GI1, the second gate insulator GI2, the first interlayer dielectric layer ILD1 and the second interlayer dielectric layer ILD2. The contact electrode CTE may be connected to the first capacitor electrode CPE1 through contact holes penetrating the second gate insulator GI2, the first interlayer dielectric layer ILD1, and the second interlayer dielectric layer ILD2. Therefore, the first to third capacitor electrodes CPE1, CPE2, and CPE3 may together form a capacitor. In addition, the first active layer ACT1, the gate electrode GE, the source electrode SE and the drain electrode DE can form a thin-film transistor TFT. The fourth conductive layer COL4 may be made up of a single layer or multiple layers of one of molybdenum (Mo), aluminum (Al), chromium (Cr), gold (Au), titanium (Ti), nickel (Ni), neodymium (Nd), and copper (Cu), or an alloy thereof.

The first via layer VIA1 may be arranged on the fourth conductive layer COL4. For example, the first via layer VIA1 may be arranged to cover the source electrode SE, the drain electrode DE, the contact electrode CTE and the second interlayer dielectric layer ILD2. The first via layer VIA1 may be formed as an organic layer such as an acryl resin, an epoxy resin, a phenolic resin, a polyamide resin, and a polyimide resin.

The fifth conductive layer COL5 may be located on the first via layer VIA1. The fifth conductive layer COL5 may include a connection electrode CNE. The connection electrode CNE may be connected to the drain electrode DE through a via hole penetrating the first via layer VIA1. The fifth conductive layer COL5 may be made up of a single layer or multiple layers of one of molybdenum (Mo), aluminum (Al), chromium (Cr), gold (Au), titanium (Ti), nickel (Ni), neodymium (Nd), and copper (Cu), or an alloy thereof.

The second via layer VIA2 may be arranged on the fifth conductive layer COL5. For example, the second via layer VIA2 may cover the connection electrode CNE. The second via layer VIA2 may be formed as an organic film such as an acryl resin, an epoxy resin, a phenolic resin, a polyamide resin, and a polyimide resin.

The emission material layer EML may include a light-emitting element ED, a bank layer PDL and a spacer SPC. The light-emitting element ED may include a pixel electrode PE, an emissive layer EL, and a common electrode CM.

The pixel electrode PE may be located on the second via layer VIA2. The pixel electrode PE may be connected to the connection electrode CNE through a via hole penetrating through the second via layer VIA2. The pixel electrode PE may include a metal material having high reflectivity, such as aluminum, titanium, ITO and an APC alloy. The APC alloy is an alloy of silver (Ag), palladium (Pd) and copper (Cu). The pixel electrode PE may be formed as a stack of aluminum and titanium (Ti/Al/Ti), a stack of aluminum and ITO (ITO/Al/ITO), a stack of an APC alloy and ITO (ITO/APC/ITO), etc.

The bank layer PDL may be a pixel-defining layer or an emission area defining layer that defines emission areas. The bank layer PDL may define the emission areas. In the emission areas, the pixel electrode PE, the emissive layer EL and the common electrode CM are stacked on one another sequentially, so that holes from the pixel electrode PE and electrons from the common electrode CM recombine in the emissive layer EL to emit light.

The bank layer PDL may be formed to cover edges of the pixel electrode PE of the light-emitting element ED. The bank layer PDL may include the spacer SPC. Although the spacer SPC and the bank layer PDL are formed integrally via the same process according to some embodiments, the present disclosure is not limited thereto. The spacer SPC and the bank layer PDL may be formed via different processes. The bank layer PDL may be formed of an organic layer such as an acryl resin, an epoxy resin, a phenolic resin, a polyamide resin and a polyimide resin.

The emissive layer EL may be located on the pixel electrode PE and the bank layer PDL. The emissive layer EL may include an organic light-emitting layer to emit light of a certain color. For example, the emissive layer EL may include a hole transporting layer, an organic emissive layer, an electron transporting layer, etc.

The common electrode CM may be located on the emissive layer EL and the bank layer PDL. The common electrode CM may cover the emissive layer EL. The common electrode CM may be formed commonly across the emission areas.

In the top-emission structure, the common electrode CM may be formed of a transparent conductive material (TCP) such as ITO and IZO that can transmit light, or a semi-transmissive conductive material such as magnesium (Mg), silver (Ag) and an alloy of magnesium (Mg) and silver (Ag). When the common electrode CM is formed of a semi-transmissive metal material, the light extraction efficiency can be increased by using microcavities.

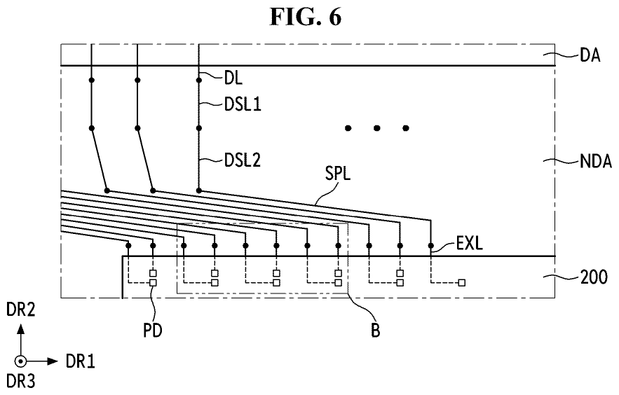

FIG. 6 is a plan view showing a non-display area of a display panel according to some embodiments of the present disclosure. For example, FIG. 6 is an enlarged view of the area A of FIG. 4.

Referring to FIG. 6, the display panel 100 may include a non-display area NDA located on one side, for example, the lower side of the display area DA. The non-display area NDA may include data lines DL, first data supply lines DSL1, second data supply lines DSL2, spider lines (e.g., interconnect lines) SPL, extension lines EXL, pad electrodes DPE, and a display driver circuit 200 arranged on the lower side of the display area DA.

The data lines DL may input data signals to a plurality of sub-pixels arranged in the display area DA. The data lines DL may be extended between the display area DA and the display driver circuit 200 and may be extended in the second direction DR2.

The first data supply line DSL1 may be arranged on the lower side of the data lines DL. The first data supply line DSL1 may connect the data line DL with the second data supply line DSL2. The first data supply line DSL1 may be extended in the second direction DR2 and be connected to the data line DL and the second data supply line DSL2 through contact holes. According to some embodiments of the present disclosure, the first data supply line DSL1 may be formed as the third conductive layer COL3 (see, e.g., FIG. 5).

The second data supply line DSL2 may be arranged on the lower side of the first data supply lines DSL1. The second data supply line DSL2 may connect the first data supply line DSL1 with the spider line SPL. The second data supply line DSL2 may be extended generally in the second direction DR2 and may be connected to the first data supply line DSL1 and the spider line SPL through contact holes. According to some embodiments of the present disclosure, the second data supply line DSL2 may be formed as the first conductive layer COL1 (see, e.g., FIG. 5) and/or the second conductive layer COL2 (see, e.g., FIG. 5). For example, one of the adjacent spider lines SPL may be formed as the first conductive layer, while the other may be formed as the second conductive layer, and the spider lines SPL may be arranged alternately when viewed from the top (i.e., in a plan view).

The spider line SPL may be arranged on the lower side of the second data supply line DSL2. For example, the spider line SPL may be located between the second data supply line DSL2 and the display driver circuit 200. The spider line SPL may connect the second data supply line DSL2 with the extension line EXL. The spider line SPL may be extended generally in the second direction DR2 and may be connected to the second data supply line DSL2 and the extension line EXL through contact holes. According to some embodiments of the present disclosure, the spider line SPL may be formed as the fourth conductive layer COL4 (see, e.g., FIG. 5) and the fifth conductive layer COL5 (see, e.g., FIG. 5). For example, one of the adjacent spider lines SPL may be formed as the fourth conductive layer COL4, while the other may be formed as the fifth conductive layer COL5, and the spider lines SPL may be arranged alternately when viewed from the top (i.e., in a plan view; as, e.g., shown in FIGS. 6-8). The spider line SPL will be described in more detail later.

The extension line EXL may be arranged between the pad electrode PDE and the spider line SPL. The extension line EXL may connect the pad electrode PDE with the spider line SPL. The extension lines EXL may be extended generally in the second direction DR2 and may be connected to the spider line SPL and the pad electrode PDE through contact holes. According to some embodiments of the present disclosure, the extension line EXL may be formed as the first conductive layer COL1 (see, e.g., FIG. 5).

The pad electrode PDE may be arranged under the display driver circuit 200. The pad electrode PDE may connect the extension line EXL with the display driver circuit 200. The extension line EXL may be connected to a bump of the display driver circuit 200 through an anisotropic conductive film. According to some embodiments of the present disclosure, the pad electrode PDE may have a stack structure of the fourth conductive layer COL4 (see, e.g., FIG. 5) and the fifth conductive layer COL5 (see, e.g., FIG. 5).

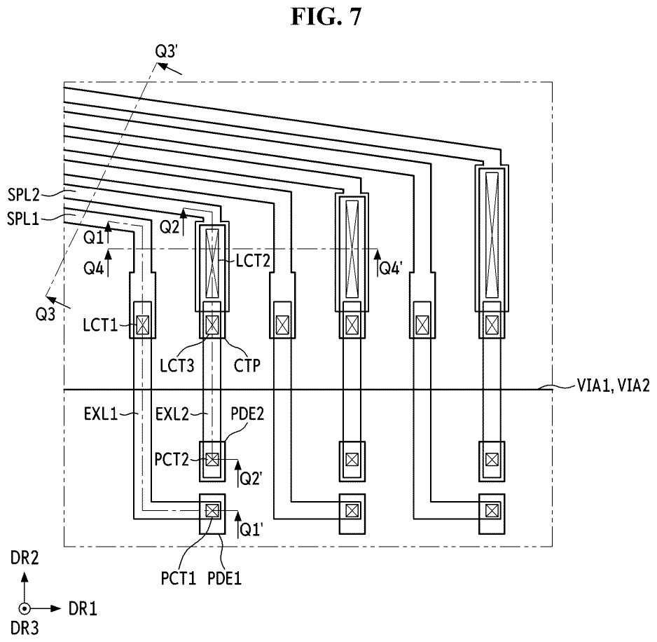

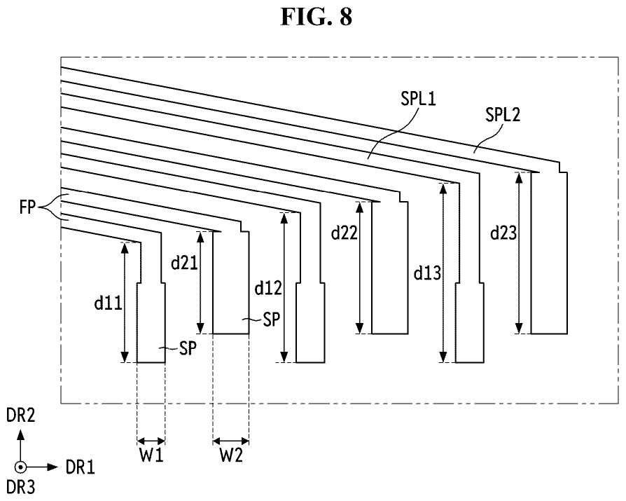

FIG. 7 is a plan view showing a portion of a non-display area of a display panel according to some embodiments of the present disclosure. FIG. 8 is a plan view showing the spider lines shown in FIG. 7, according to some embodiments of the present disclosure. For example, FIG. 7 is an enlarged view of the area B of FIG. 6. FIG. 8 shows only the spider lines shown in FIG. 7.

Referring to FIG. 7 and FIG. 8 in conjunction with FIG. 6, spider lines SPL, extension lines EXL and pad electrodes PDE may be arranged in the non-display area NDA.

The spider lines SPL may be extended downward, for example, toward the display driver circuit 200 from an area adjacent to the display area DA. The spider lines SPL may be extended in a direction, bent and then extended.

The spider lines SPL may include a first spider line SPL1 and a second spider line SPL2. The first spider lines SPL1 and the second spider lines SPL2 may be arranged alternately in a direction (e.g., the first direction D1) when viewed from the top (i.e., in a plan view).

Each of the first spider line SPL1 and the second spider line SPL2 may include a first region FP and a second region SP. The first region FP may refer to a portion of each of the first spider line SPL1 and the second spider line SPL2 that is extended diagonally. The second region SP may refer to a portion of each of the first spider line SPL1 and the second spider line SPL2 that is extended vertically (e.g., in the second direction DR2). The second region SP of each of the first spider line SPL1 and the second spider line SPL2 may be bent from the first region FP and may be closer to the display driver circuit 200 than the first region FP. The second region SP of the first spider line SPL1 may be extended further downward than the second region SP of the second spider line SPL2 when viewed from the top (i.e., in a plan view). For example, the second region SP of the first spider line SPL1 may protrude further toward the display driver circuit 200 (e.g., downward) than the second region SP of the second spider line SPL2.

The first regions FP of the first spider line SPL1 and the second spider line SPL2 may have the same width. For example, the width of the first region FP of the first spider line SPL1 may be equal to the width of the first region FP of the second spider line SPL2.

The first spider line SPL1 and the second spider line SPL2 may have different lengths of the second region SP. For example, the length of the second region SP of the first spider line SPL1 may be different from the length of the second region SP of the second spider line SPL2. Herein, the length may refer to the extended length of each of the spider lines SPL1 and SPL2 measured in the second direction DR2. According to some embodiments of the present disclosure, the first length d11 of the second region SP of the first spider line SPL1 on one side may be different from the first length d21 of the second region SP of the adjacent second spider line SPL2. According to some embodiments of the present disclosure, the first length d21 of the second region SP of the second spider line SPL2 may be larger than the first length d11 of the second region SP of the first spider line SPL1.

In addition, the second regions SP of the first spider lines SPL1 may have different lengths. For example, the lengths of the second regions SP of the first spider lines SPL1 spaced apart from each other in the first direction DR1 may be different from each other. For example, the first length d11 of the second region SP of the first one of first spider lines SPL1 may be smaller than the second length d12 of the second region SP of the second one. The second length d12 of the second region SP of the second one may be smaller than the third length d13 of the second region SP of the third one. According to some embodiments of the present disclosure, the lengths of the second regions SP of the first spider lines SPL1 may increase in the direction toward the first direction DR1.

The second regions SP of the second spider lines SPL2 may have different lengths. For example, the lengths of the second regions SP of the second spider lines SPL2 spaced apart from each other in the first direction DR1 may be different from each other. For example, the first length d21 of the second region SP of the first one of second spider lines SPL2 may be smaller than the second length d22 of the second region SP of the second one. The second length d22 of the second region SP of the second one may be smaller than the third length d23 of the second region SP of the third one. According to some embodiments of the present disclosure, the lengths of the second regions SP of the second spider lines SPL2 may increase in the direction toward the first direction DR1.

Because the second regions SP of the first spider lines SPL1 and the second spider lines SPL2 have different lengths, deviations in the line resistance of the first spider lines SPL1 and the second spider lines SPL2 can be reduced, so that the display quality can be improved.

The first spider lines SPL1 may have the same width W1, and the second spider lines SPL2 may be the same width W2. The second regions SP of the spider lines SPL1 and SPL2 may have different widths. For example, the width W1 of the second region SP of the first spider line SPL1 may be smaller than the width W2 of the second region SP of the second spider line SPL2. As described below, the width W2 of the second region SP of the second spider line SPL2 may be made larger than the width W1 of the second region SP of the first spider line SPL1 in order to come in contact with the contact pattern CTP formed as the same fourth conductive layer COL4 (see, e.g., FIG. 5) as the first spider line SPL1.

The extension lines EXL may connect the spider lines SPL1 and SPL2 with the pad electrodes PDE1 and PDE2, respectively. The extension lines EXL may be extended in the second direction DR2, and may be bent and extended in the first direction DR1. The extension lines EXL may include a first extension line EXL1 and a second extension line EXL2. The first extension line may connect the first spider line SPL1 with the first pad electrode PDE1, and the second extension line EXL2 may connect the second spider line SPL2 with the second pad electrode PDE2.

The pad electrodes PDE may overlap (e.g., in the plan view) with the display driver circuit 200. The pad electrodes PDE may overlap with the ends of the extension lines EXL. The pad electrodes PDE may include a first pad electrode PDE1 and a second pad electrode PDE2. The first pad electrode PDE1 may be connected to the first extension line EXL1, and the second pad electrode PDE2 may be connected to the second extension line EXL2. The first pad electrode PDE1 and the second pad electrode PDE2 may be spaced apart from each other in the second direction DR2, but the present disclosure is not limited thereto.

The first extension line EXL1 may be connected to the first pad electrode PDE1 via a first pad contact portion PCT1 overlapping with the first pad electrode PDE1. The second extension line EXL2 may be connected to the second pad electrode PDE2 via a second pad contact portion PCT2 overlapping with the second pad electrode PDE2.

The contact pattern CTP may be arranged at the end of each of the second spider lines SPL2. For example, the contact pattern CTP may overlap (e.g., in the plan view) with the end of each of the second spider lines SPL2. The contact pattern CTP may be formed as the same fourth conductive layer COL4 (see, e.g., FIG. 5) as the first spider line SPL1, to connect the second spider line SPL2 with the second extension line EXL2. The width of the contact pattern CTP may be smaller than the width of the second region SP of the second spider line SPL2. The width of the contact pattern CTP may be larger than the width of the second extension line EXL2. The contact pattern CTP may overlap with the second spider line SPL2 and the second extension line EXL2 when viewed from the top (i.e., in a plan view).

According to some embodiments of the present disclosure, the contact patterns CTP may have different lengths (e.g., which extend in the second direction DR2). For example, the length of the contact pattern CTP overlapping with the first one of the second spider lines SPL2 from the left side of the drawing may be smaller than the length of the contact pattern CTP overlapping with the second one. The length of the contact pattern CTP overlapping with the second one of the second spider line SPL2 may be smaller than the length of the contact pattern CTP overlapping with the third one. According to some embodiments of the present disclosure, the lengths of the contact patterns CTP may increase along the first direction DR1.

The first spider line SPL1 may be connected to the first extension line EXL1 through a first contact portion LCT1 overlapping with the first extension line EXL1. The second spider line SPL2 may be connected to the contact pattern CTP through a second contact portion LCT2 overlapping with the contact pattern CTP. The contact pattern CTP may be connected to the second extension line EXL2 via a third contact portion LCT3 overlapping with the second extension line EXL2. Accordingly, the second spider line SPL2 may be electrically connected to the second extension line EXL2 through the contact pattern CTP.

According to some embodiments, the length and area of the second contact portion LCT2 where the second spider line SPL2 and the contact pattern CTP are connected may be greater than the length and area of the first contact portion LCT1 connected to the first spider line SPL1 and the first extension line EXL1, and the length and area of the third contact portion LCT3 connected to the contact pattern CTP and the second extension line EXL2. As the length and area of the second contact portion LCT2 where the second spider line SPL2 and the contact pattern CTP are connected are larger, the adhesive strength between the second spider line SPL2 and the contact pattern CTP can be increased, so that it is possible to prevent the second spider line SPL2 from being disconnected during a rework process of the display driver circuit 200 to be described later.

In addition, the length and area of each second contact portion LCT2 may increase along the direction toward the first direction DR1. For example, the length and area of the first one of the second contact portions LCT2 from the left side of the drawing may be smaller than the length of the second one of the second contact portions LCT2, and the length and area of the second one of the second contact portions LCT2 may be smaller than the length and area of the third one of the second contact portions LCT2. According to some embodiments of the present disclosure, the lengths and areas of the each second contact portions LCT2 may increase along the first direction DR1.

Hereinafter, the cross-sectional structures of the spider lines SPL1 and SPL2, the extension lines EXL1 and EXL2, and the pad electrodes PDE1 and PDE2 will be further described with reference to other drawings.

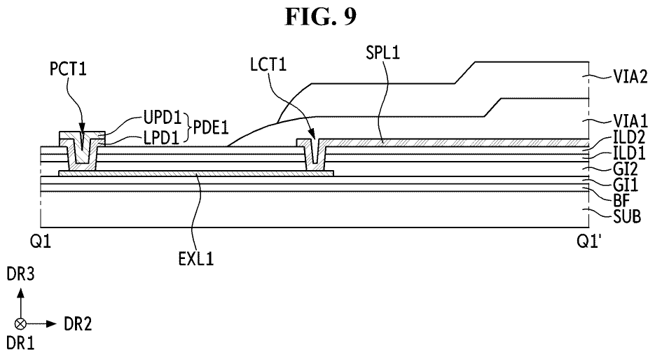

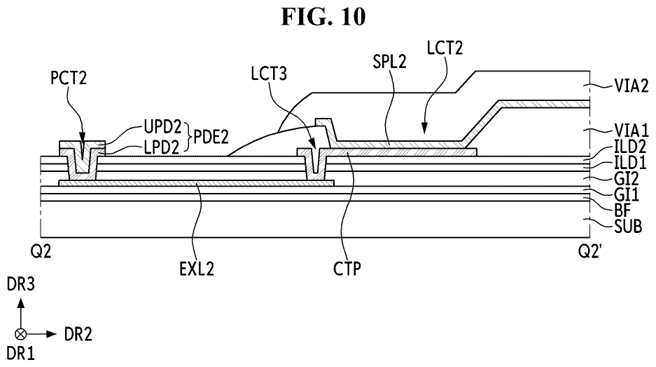

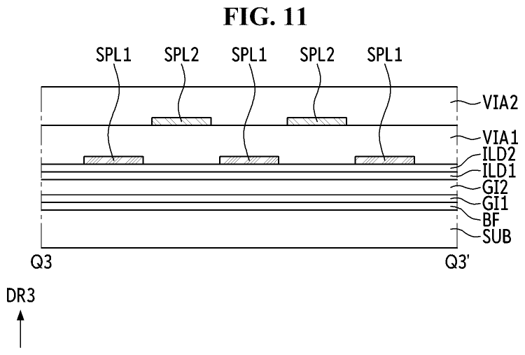

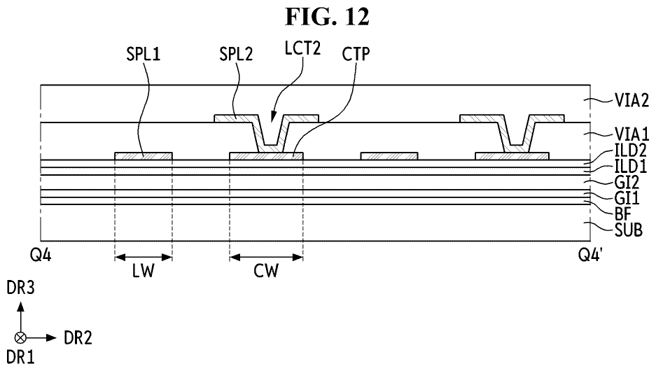

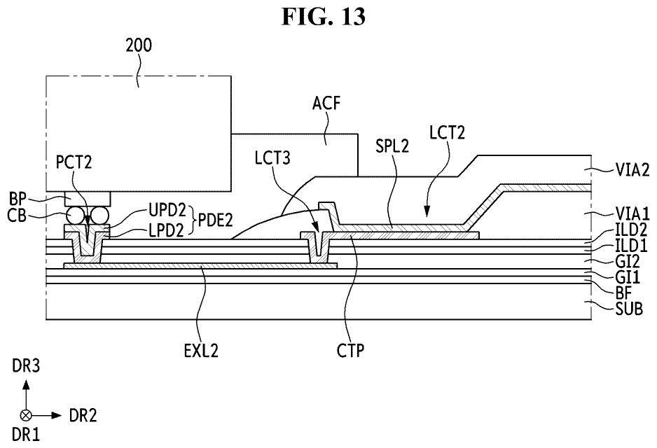

FIG. 9 is a cross-sectional view taken along the line Q1-Q1′ of FIG. 7, according to some embodiments of the present disclosure. FIG. 10 is a cross-sectional view taken along the line Q2-Q2′ of FIG. 7, according to some embodiments of the present disclosure. FIG. 11 is a cross-sectional view taken along the line Q3-Q3′ of FIG. 7, according to some embodiments of the present disclosure. FIG. 12 is a cross-sectional view taken along the line Q4-Q4′ of FIG. 7, according to some embodiments of the present disclosure. FIG. 13 is a cross-sectional view taken along the line Q2-Q2′ of FIG. 7, according to some embodiments of the present disclosure.

Referring to FIGS. 9 to 13, the buffer layer BF and the first gate insulator GI1 may be sequentially stacked and arranged on the substrate SUB, and a first extension line EXL1 and a second extension line EXL2 may be arranged on the first gate insulator GI1. The first extension line EXL1 and the second extension line EXL2 may be formed as the first conductive layer COL1 (see, e.g., FIG. 5) described above.

A second gate insulator GI1, a first interlayer dielectric layer ILD1 and a second interlayer dielectric layer ILD2 may be sequentially stacked and arranged on the first extension line EXL1 and the second extension line EXL2. A first spider line SPL1, a contact pattern CTP, a first lower pad electrode LPD1 and a second lower pad electrode LPD2 may be arranged on the second interlayer dielectric layer ILD2. The first spider line SPL1, the contact pattern CTP, the first lower pad electrode LPD1 and the second lower pad electrode LPD2 may be formed as the fourth conductive layer COL4 (see, e.g., FIG. 5) described above.

The first spider line SPL1 may be connected to the first extension line EXL1 through a first contact portion LCT1 that penetrates the second gate insulator GI1, the first interlayer dielectric layer ILD1, and the second interlayer dielectric layer ILD2. The first lower pad electrode LDP1 may be connected to the first extension line EXL1 through the first contact portion LCT1 that penetrates the second gate insulator GI1, the first interlayer dielectric layer ILD1, and the second interlayer dielectric layer ILD2. The contact pattern CTP may be connected to the extension line EXL2 through the third contact portion CLT3 penetrating the second gate insulator GI2, the first interlayer dielectric layer ILD1, and the second interlayer dielectric layer ILD2. The second lower pad electrode LDP2 may be connected to the second extension line EXL2 through the second contact portion LCT2 that penetrates the second gate insulator GI1, the first interlayer dielectric layer ILD1, and the second interlayer dielectric layer ILD2.

A first via layer VIA1 may be arranged on the first spider line SPL1 and the contact pattern CTP. The first via layer VIA1 may be extended from the display area DA to the non-display area NDA.

A second spider line SPL2 may be arranged on the first via layer VIA1. The second spider line SPL2 may be connected to the contact pattern CTP through the second contact portion LCT2 penetrating the first via layer VIA1. In addition, a first upper pad electrode UPD1 and a second upper pad electrode UPD2 may be arranged on the first lower pad electrode LPD1 and the second lower pad electrode LPD2. For example, the first upper pad electrode UPD1 may be arranged on the first lower pad electrode LPD1, and the second upper pad electrode UPD2 may be arranged on the second lower pad electrode LPD2. The second spider line SPL2, the first upper pad electrode UPD1, and the second upper pad electrode UPD2 may be formed as the fifth conductive layer COL5 (see, e.g., FIG. 5) described above.

A second via layer VIA2 may be arranged on the first via layer VIA1 and the second spider line SPL2. The second via layer VIA2 may partially expose a portion of the first via layer VIA1.

As shown in FIG. 11, in the first region FP of each of the spider lines SPL1 and SPL2, the spider lines SPL1 and SPL2 may be arranged in different layers and arranged alternately when viewed from the top (i.e., in a plan view). For example, the first spider line SPL1 may be arranged between the first interlayer dielectric layer ILD1 and the second interlayer dielectric layer ILD2, and the second spider line SPL2 may be arranged on the first via layer VIA1. As the first spider line SPL1 and the second spider line SPL2 are arranged in different layers, the gap (e.g., when viewed in a plan view) between the first spider line SPL1 and the second spider line SPL2 can be reduced, allowing more spider lines to be placed within the given non-display area NDA.

As shown in FIG. 12, in the second region SP of each of the spider lines SPL1 and SPL2, the first spider line SPL1 and the contact pattern CTP may be arranged at the same layer and the spider lines SPL may be arranged alternately when viewed from the top. For example, the first spider line SPL1 and the contact pattern CTP may be arranged directly on the second interlayer dielectric layer ILD2. According to some embodiments of the present disclosure, the minimum width LW of the second region SP of the first spider line SPL1 may be smaller than the width CW of the contact pattern CTP.

As shown in FIG. 13, the display driver circuit 200 may be coupled on the pad electrodes PDE via an anisotropic conductive film ACF. The display driver circuit 200 may include a plurality of bumps BP on the lower side, and the anisotropic conductive film ACF may include a plurality of conductive balls CB. According to some embodiments, the anisotropic conductive film ACF may be applied on the substrate SUB and the display driver circuit 200 may be bonded by thermal compression. In this instance, the bumps BP of the display driver circuit 200 may be electrically connected to the pad electrodes PDE through the conductive balls CB.

The display driver circuit 200 may overlap (e.g., in the plan view) with the extension lines EXL1 and EXL2 and may not overlap with the first spider line SPL1, the second spider line SPL2 or the contact pattern CTP. The anisotropic conductive film ACF may overlap with the pad electrodes PDE1 and PDE2, the extension lines EXL1 and EXL2, the contact pattern CTP, the first spider line SPL1 and the second spider line SPL2.

According to some embodiments, the size of the first contact portion LCT1 connected to the first spider line SPL1 and the first extension line EXL1 may be equal to the size of the third contact portion LCT3 connected to the contact pattern CTP and the second extension line EXL2. The size of the second contact portion LCT2 where the second spider line SPL2 and the contact pattern CTP are connected may be larger than the sizes of the first contact portion LCT1 and the third contact portion LCT3. As described below, in a rework process of the display driver circuit 200, the first via layer VIA1 may be separated when the display driver circuit 200 is removed. When this happens, the second spider line SPL2 located on the first via layer VIA1 may also be separated, such that the second spider line SPL2 may be disconnected.

According to some embodiments, by increasing the size of the second contact portion LCT2 where the second spider line SPL2 and the contact pattern CTP are connected, the contact area between the second spider line SPL2 and the contact pattern CTP can be increased. As the contact area between the second spider line SPL2 and the contact pattern CTP is increased, it is possible to prevent the second spider line SPL2 from being separated when the first via layer VIA1 is separated.

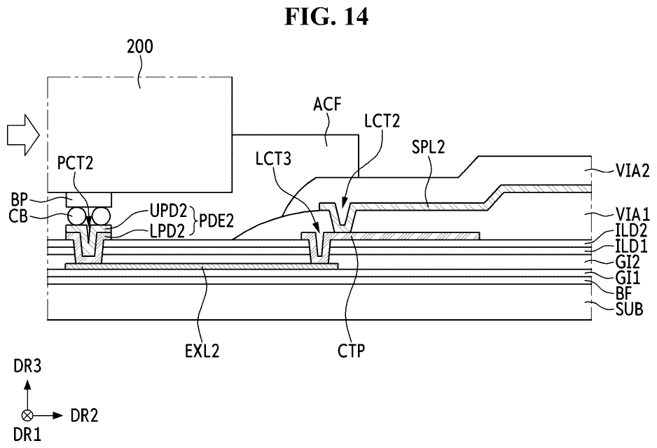

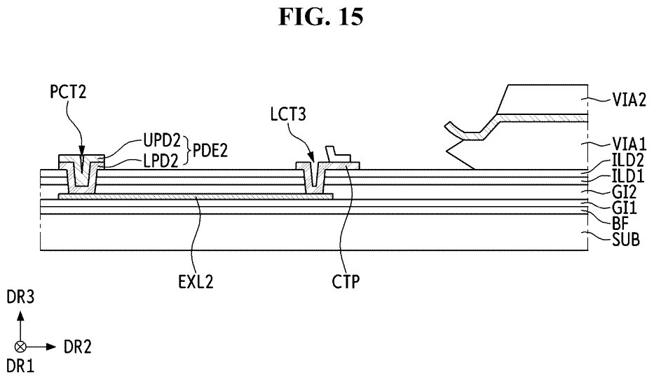

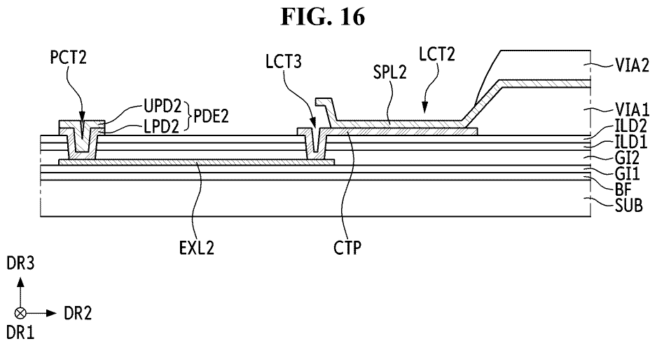

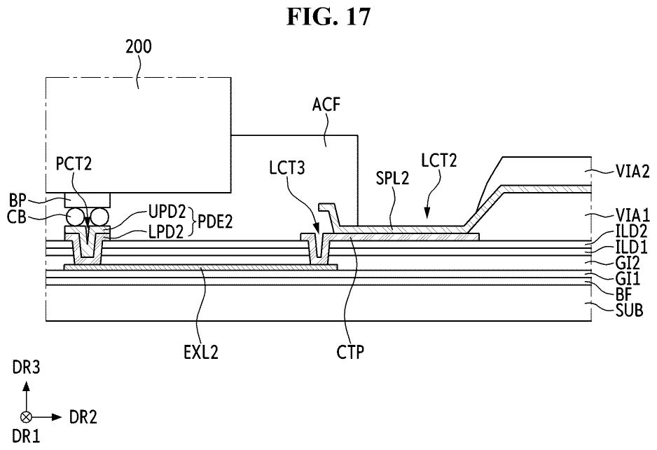

FIGS. 14 and 15 are cross-sectional views showing a rework process of a display driver circuit, according to some embodiments of the present disclosure. FIGS. 16 and 17 are cross-sectional views showing a display device according to some embodiments of the present disclosure.

In the example shown in FIGS. 14 and 15, the size of a second contact portion LCT2 where a second spider line SPL2 and a contact pattern CTP are connected is substantially equal to the size of a third contact portion LCT3 where the contact pattern CTP and a second extension line EXL2 are connected. FIG. 16 shows an example of a display driver circuit 200 after a rework process according to some embodiments in which the size of the second contact portion LCT2 where the second spider line SPL2 and the contact pattern CTP are connected is larger than the size of the third contact portion LCT3 where the contact pattern CTP and the second extension line EXL2 are connected. FIG. 17 shows the display driver circuit 200 recombined with the display device of FIG. 16. FIGS. 16 and 17 disclosed below show some other embodiments different from the structure of FIG. 13 described above.

Referring to FIGS. 14 and 15, separation of the second spider line SPL2 during a rework process of the display driver circuit 200 will be described.

If a defect occurs in the combination of the display driver circuit 200, a rework process may be performed, that is, the display driver circuit 200 is disassembled and then recombined (e.g., by attaching a new display driver circuit or reusing the existing display driver circuit). The rework process may be performed by applying heat to the display driver circuit 200 while applying force in a direction to disassemble the display driver circuit 200.

As shown in FIG. 15, when the display driver circuit 200 is detached, the anisotropic conductive film ACF may also be removed together. When this happens, the first via layer VIA1 and the second via layer VIA2 adhered to the anisotropic conductive film ACF may be separated together. This is because the via layers VIA1 and VIA2 are made of organic materials, and thus the adhesive strength between the organic materials and the organic adhesive components of the anisotropic conductive film ACF is large. On the other hand, the pad electrodes PDE or the second interlayer dielectric layer ILD2 are made of metal or inorganic materials, and thus they are not separated because the adhesive strength between the organic adhesive components of the anisotropic conductive film ACF and the metal or inorganic materials is relatively small.

Most portion of the second spider line SPL2 is located on the first via layer VIA1, and thus the second spider line SPL2 may be separated together with the first via layer VIA1 except for some portions in contact with the contact pattern CTP. In other words, the second spider line SPL2 may be broken and disconnected (e.g., may become an electrical open), as shown in FIG. 15.

Referring to FIG. 16, according to some embodiments of the present disclosure, the size of the second contact portion LCT2 where the second spider line SPL2 and the contact pattern CTP are connected may be larger than the size of the third contact portion LCT3 where the contact pattern CTP and the second extension line EXL2 are connected. Accordingly, the contact area between the second spider line SPL2 and the contact pattern CTP can be increased, thereby increasing the adhesive strength between the second spider line SPL2 and the contact pattern CTP. In addition, as described above, the length of the second region SP of the second spider line SPL2 increases along the first direction DR1, and the length and area of each second contact portion LCT2 increase along the first direction DR1, and accordingly the adhesive strength between the second spider line SPL2 and the contact pattern CTP can also further increase along the first direction DR1. In this manner, it is possible to prevent the second spider line SPL2 from being separated (e.g., lifted off the contact pattern CTP and broken off from the structure) even if the first via layer VIA1 is removed during the rework process of the display driver circuit 200, because the adhesive strength between the second spider line SPL2 and the contact pattern CTP is large.

Referring to FIG. 17, the display driver circuit 200 may be recombined and arranged by the rework process of the display driver circuit 200. The anisotropic conductive film ACF may be placed on the second interlayer dielectric layer ILD2, the contact pattern CTP and the second spider line SPL2, and bumps BP of the display driver circuit 200 may be connected with and pad electrodes PDE through conductive balls CB.

As described above, according to some embodiments, by increasing the contact area between the second spider line SPL2 and the contact pattern CTP to improve the adhesive strength, it is possible to address the defect of the second spider line SPL2 being disconnected during the rework process of the display driver circuit 200.

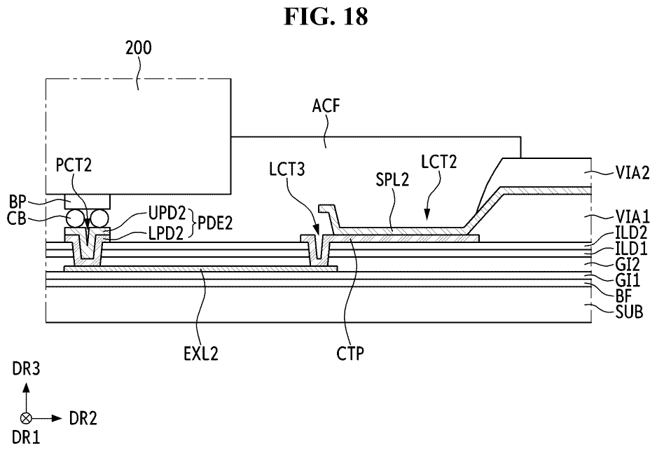

FIG. 18 is a cross-sectional view showing a display device according to some other embodiments of the present disclosure.

Referring to FIG. 18, according to some embodiments, an anisotropic conductive film ACF may cover a second spider line SPL2. The anisotropic conductive film ACF may be located on and cover a second interlayer dielectric layer ILD2, a contact pattern CTP, a second spider line SPL2 and a second via layer VIA2. The anisotropic conductive film ACF may be located on a first spider line SPL1 to cover the first spider line SPL1.

According to some embodiments of the present disclosure, the anisotropic conductive film ACF may be in direct contact with a portion of the second spider line SPL2. For example, the second via layer VIA2 may expose a portion of the second spider line SPL2, and the anisotropic conductive film ACF may be in direct contact with the second spider line SPL2 exposed by the second via layer VIA2. As another example, the anisotropic conductive film ACF may cover a portion of the second via layer VIA2 and may be in direct contact with the entire second spider line SPL2 exposed by the second via layer VIA2.

By covering the second spider line SPL2 with the anisotropic conductive film ACF, it is possible to prevent the second spider line SPL2 from being corroded by outside moisture and oxygen or substantially reduce the likelihood thereof.

The display device according to some embodiments may be applied to a variety of electronic devices. An electronic device according to some embodiments includes the display device described above, and may further include a module or device having additional features in addition to the display device.

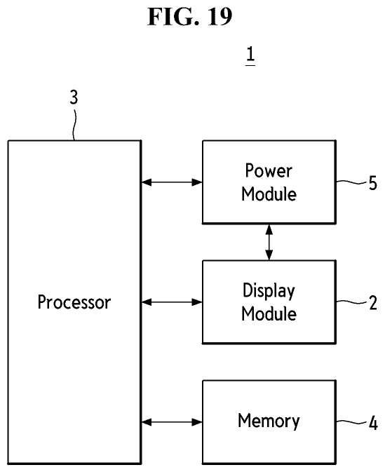

FIG. 19 is a block diagram of an electronic device according to some embodiments of the present disclosure. Referring to FIG. 19, an electronic device 1 according to some embodiments of the present disclosure may include a display module 2, a processor 3, a memory 4, and a power module 5.

The processor 3 may include at least one of: a central processing unit (CPU), an application processor (AP), a graphic processing unit (GPU), a communication processor (CP), an image signal processor (ISP), and a controller.

The memory 4 may store data information required for the operation of the processor 12 or the display module 2. When the processor 3 executes an application stored in the memory 4, an image data signal and/or an input control signal may be transmitted to the display module 2. The display module 2 may process the received signal and output image information through a display screen.

The power module 5 may include a power supply module such as a power adapter and a battery device, and a power conversion module that converts the power supplied by the power supply module to generate power required for the operation of the electronic device 1.

At least one of the elements of the electronic device 1 described above may be included in the display devices according to the embodiments described above. In addition, some of the individual modules functioning as a single module may be included in the display device while some others may be provided separately from the display device. For example, the display device may include the display module 2, and the processor 3, the memory 4, and the power module 5 may be implemented as other devices inside the electronic device 1 instead of the display device.

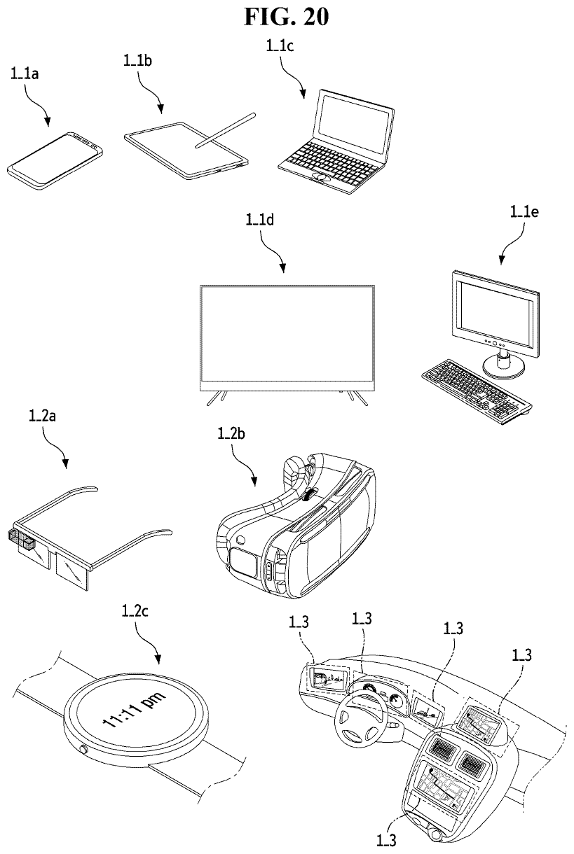

FIG. 20 is a view showing electronic devices according to a variety of embodiments of the present disclosure.

Referring to FIG. 20, a variety of electronic devices employing display devices according to some embodiments may include not only image display electronic devices such as a smart phone 1_1a, a tablet PC 1_1b, a laptop computer 1_1c, a TV 1_1d and a desktop monitor 1_1e, but also wearable electronic devices including display modules such as smart glasses 1_2a, a head-mounted display 1_2b and a smart watch 1_2c, and electronic devices for vehicles 1_3 including display modules such as a center information display (CID) placed on the dashboard, the center fascia and the dashboard of a vehicle, and a room mirror display.

In concluding the detailed description, those skilled in the art will appreciate that many variations and modifications can be made to the described embodiments without substantially departing from the principles of the present invention, the scope of which is defined by the following claims and equivalents thereof. Therefore, the disclosed preferred embodiments of the invention are used in a generic and descriptive sense only and not for purposes of limitation.

What is claimed is:

1. A display device comprising:
a substrate comprising a display area comprising a plurality of pixels and a non-display area located around the display area;
data lines extended from the display area;
a display driver circuit in the non-display area and on one side of the display area;
pad electrodes connected to the display driver circuit;
extension lines extended from the pad electrodes;
interconnect lines connecting the data lines with the extension lines, and comprising a first interconnect line and a second interconnect line spaced apart from each other; and
a contact pattern overlapping with one of the second interconnect line and the extension lines,
wherein the first interconnect line is connected to an extension line of the extension lines through a first contact portion,
wherein the second interconnect line is connected to the contact pattern through a second contact portion, and
wherein a size of the second contact portion is larger than a size of the first contact portion.

2. The display device of claim 1, wherein the contact pattern is connected to the extension line overlapping with the contact pattern through a third contact portion.

3. The display device of claim 2, wherein the size of the second contact portion is larger than a size of the third contact portion.

4. The display device of claim 1, wherein the first interconnect line and the second interconnect line are at different layers.

5. The display device of claim 1, wherein a width of the contact pattern is greater than a width of the extension line.

6. The display device of claim 1, wherein a width of the second interconnect line is greater than a width of the contact pattern.

7. The display device of claim 1, wherein the second interconnect line protrudes further in a direction toward the display driver circuit than the first interconnect line.

8. The display device of claim 1, wherein each of the first interconnect line and the second interconnect line comprises a first region and a second region, and
wherein the second region is bent from the first region and closer to the display driver circuit.

9. The display device of claim 8, wherein a width of the first region of the first interconnect line is equal to a width of the first region of the second interconnect line.

10. The display device of claim 8, wherein a length of the second region of the second interconnect line is different from a length of the first region of the first interconnect line.

11. The display device of claim 10, wherein the length of the second region of the second interconnect line is larger than the length of the first region of the first interconnect line.

12. The display device of claim 8, wherein a length of the second region of the first interconnect line is different from a length of another first interconnect line, and
wherein a length of the second region of the second interconnect line is different from a length of another second interconnect line.

13. The display device of claim 12, wherein lengths of the second regions of the first interconnect lines and lengths of the second regions of the second interconnect lines increase along a direction.

14. A display device comprising:
a substrate;
extension lines arranged on the substrate;
a plurality of insulating layers arranged on the extension lines;
a first interconnect line and a contact pattern arranged on the plurality of insulating layers, and the contact pattern is spaced apart from the first interconnect line;
a first via layer arranged on the contact pattern;
a second interconnect line arranged on the first via layer;
pad electrodes arranged on the plurality of insulating layers and overlapping with the extension lines; and
a display driver circuit arranged on the pad electrodes,
wherein the first interconnect line is connected to one of the extension lines through a first contact portion penetrating the plurality of insulating layers,
wherein the second interconnect line is connected to the contact pattern through a second contact portion penetrating the first via layer,
wherein the contact pattern is connected to another one of the extension lines through a third contact portion penetrating the plurality of insulating layers, and
wherein a size of the second contact portion is larger than a size of the first contact portion and a size of the third contact portion.

15. The display device of claim 14, wherein the pad electrodes are connected to the extension lines through pad contact holes penetrating the plurality of insulating layers,
wherein the pad electrodes comprises a lower pad electrode in contact with the extension lines, and an upper pad electrode located on the lower pad electrode,
wherein the extension lines comprise a first conductive layer,
wherein the lower pad electrode, the first interconnect line, and the contact pattern comprise a second conductive layer, and
wherein the upper pad electrode and the second interconnect line comprise a third conductive layer.

16. The display device of claim 14, further comprising:
an anisotropic conductive film between the display driver circuit and the pad electrodes and comprising a conductive ball,
wherein the display driver circuit comprises bumps, and
wherein the bumps and the pad electrodes are connected through the conductive ball.

17. The display device of claim 16, wherein the anisotropic conductive film covers at least a portion of the second interconnect line and is in contact with the second interconnect line.

18. The display device of claim 16, further comprising:
a second via layer located on the second interconnect line,
wherein the second via layer exposes at least a portion of the second interconnect line, and
wherein the anisotropic conductive film covers a portion of the second via layer and the second interconnect line exposed by the second via layer.

19. The display device of claim 14, wherein the display driver circuit overlaps with the extension lines and does not overlap with the first interconnect line or the second interconnect line.

20. An electronic device comprising a display device, a display module, a processor, a memory and a power module, the display device comprising:
a substrate comprising a display area comprising a plurality of pixels and a non-display area located around the display area;
data lines extended from the display area;
a display driver circuit in the non-display area and on one side of the display area;
pad electrodes connected to the display driver circuit;
extension lines extended from the pad electrodes;
interconnect lines connecting the data lines with the extension lines, and comprising a first interconnect line and a second interconnect line spaced apart from each other; and
a contact pattern overlapping with one of the second interconnect line and the extension lines,
wherein the first interconnect line is connected to an extension line of the extension lines through a first contact portion,
wherein the second interconnect line is connected to the contact pattern through a second contact portion, and
wherein a size of the second contact portion is larger than a size of the first contact portion.
